(19) United States
(12) Patent Application Publication
(10) Pub. No.: US 2003/0181042 A1
(43) Pub. Date: Sep. 25, 2003

(54) Etching uniformity in wet bench tools

(75) Inventors: Jian Hung Chen, Hsin Chu (TW); Chih Che Huang, Kaohsiung (TW); Ming-Hsun Yang, Tainan (TW); Chii Shing Yang, Kaohsiung (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/102,573

(22) Filed: Mar. 19, 2002

(51) Int. Cl. H01L 21/302; H01L 21/461

(52) U.S. Cl. 438/689

(57) ABSTRACT

Method of wet etching a semiconductor wafer comprises immersing the wafer into a chemical bath filled with etchant solution, keeping the wafer in the etchant for predetermined time, and taking it out of the etchant upon completing etching. While in the bath, the wafer is turned upside down around an axis normal to its plane to provide for equalizing etching time for various areas of the wafer and thus to contribute to higher wafer etching uniformity.

### BACKGROUND OF THE INVENTION

1. Field of the Invention

The present invention relates generally to the process of manufacturing semiconductor devices, and more particularly to etching films on semiconductor wafers in a chemical bath. Still more particularly, the invention pertains to improving uniformity of the etching stage.

2. Description of the Related Art

Generally, the process of manufacturing semiconductor devices involves a wide variety of steps including a layer formation process for forming multiple layers such as a polycrystalline layer, an oxide layer, a nitride layer, a metal layer, etc. on a wafer as a semiconductor substrate. These steps generally also include a diffusion process, a photolithography process, an etching process, a cleaning process, an ion implantation process, and the like, which are carried out between the steps of layer formation.

Etching is a process, in which selected material is removed from a silicon substrate or from thin films on the substrate surface. In one type of selective etching, a mask layer is used to protect specific regions of a substrate on a wafer surface. Then, a selective etch removes material not covered by the mask. In another type of selective etching, self-aligned silicide, a metal is deposited over the substrate structure and reacted with exposed silicon areas to form a silicide. Then, a selective etch removes the unreacted metal without attacking the silicide.

In the manufacturing process of semiconductor devices, etching can be performed through two methods: one is dry etching using gas; another is wet etching using wet chemical. Plasma etching, ion beam etching and reactive ion etching are included in the former, and immersion etching and spray etching are included in the latter.

In the process of manufacturing semiconductor devices, integrated circuit fabrication processes that use reactive plasmas for that purpose are commonplace in today's semiconductor production lines because of their potential for very high-accuracy transfer of resist patterns, i.e., anisotropic etching. By contrast, wet chemical etching results in isotropic etching, where both vertical and lateral etch rates are comparable. Nevertheless, wet etching is still the practical alternative for a high-throughput, flexible production process. With properly selected chemicals, etch reactions with the primary film are thermodynamically favored over reactions with the other films. The etch-rate ratio usually approaches infinity. Wet etches are especially suitable for blanket etches of polysilicon, oxide, nitride, and metal. Recently, there has been a resurgence of wet etching for certain process steps because plasma etching fails to provide the required etch selectivity, damage-free interface, and particle-contamination-free wafers. Using robotic handling and ultra-pure chemicals has improved particle control and process consistency. These improvements have revived wet etching processes for VLSI processing.

In a wet selective etching process, the substrate is etched through exposure to a liquid etchant. The liquid etchant removes a predetermined amount of the uncovered or unreacted material and, thereby, forms patterns in the substrate. Two basic wet etching techniques are spray etching and immersion etching. Spray etching offers several advantages over immersion etching. Spray etching requires less volume of chemicals and is faster than immersion etching. Good process control and etch uniformity are easily obtained from spray etching because fresh etchant is constantly supplied to the wafer surface while the etch products are continuously removed. Spin spray etching may employ an apparatus for wafer treatment including a spin chuck used to rotate the wafer when it is mounted on the spin chuck. Single wafer spinning-chuck spray systems offer considerable process uniformity advantages.

In a conventional spin-etching device, a semiconductor wafer is horizontally placed on and fixed to a turntable of a spin etching device. While the wafer is rotating around a vertical axis, an etching solution is supplied from a nozzle disposed above the wafer, dropping onto a substantially central area thereof. The wafer is etched by the etching solution as it is uniformly scattered over the semiconductor wafer under centrifugal forces. The above-described etching system offers considerable process uniformity advantages. However, spin etching using viscous etchants such as sulfuric acid and phosphoric acid have generally failed to provide a uniform etch because the viscous etchants cannot spread uniformly across the wafer surface. The result is an incomplete etch or an undercutting of the surface layer, reducing the chip yield. The etch uniformity across the wafer becomes very important as film thickness is reduced, device dimensions shrink and wafer size increases. Therefore, an improved wet etching process that ensures a uniform etch is highly desirable.

In comparison with spray etching, immersion etching is a more simple technique. The masked or unmasked wafer is submerged in the etch solution, and mechanical agitation is usually required to ensure etch uniformity and a consistent etch rate. In immersion etching, when the wafers, on which insulating layers are deposited, are immersed in wet chemical etchant in an inner bath, the insulating layers are etched to the predetermined depth. In this case, the wet chemical etchant is continuously supplied to the inner bath by a circulation system and hence overflows the upper end of each sidewall of the inner bath. One problem with this method is that etching residue can remain floating around the top surface of the wet chemical etchant. This residue can impair the etching process by reducing the etching speed for the wafer, thus causing different wafers in the same chemical pool to etch at different rates. The overflowing of the wet chemical etchant is meant to flush out this residue, but it may not be uniformly successful.

Also in this process, it is nearly impossible to maintain the horizontal balance of the inner bath. As a result, if, for example, the right-positioned sidewall of the inner bath slopes lightly lower than the left-positioned sidewall, the amount of the wet chemical flowing over the upper end of the right sidewall of the inner bath may be larger than that flowing over the upper end of the left sidewall. Likewise, if the left-positioned sidewall slopes lower than the right-positioned sidewall, the wet chemical flowing over the upper end of the left sidewall of the inner bath may be larger than that flowing over the upper end of the right sidewall.

This difference in flow rates over the sidewalls of the inner bath becomes particularly important when the role of the overflow in eliminating etching residue is considered. If one side overflows at a quicker pace than another, wafers closer to that side will have less etching residue interfering with etching and will thus have a greater etch rate. The difference of the etching rate between wafers is undesirable.

Therefore, unless an accurate horizontal balance of the inner bath is maintained, the amount of the overflowing wet chemical may differ at the various sides of the inner bath. This makes it difficult to obtain a uniform etching rate for the entire plurality of wafers and diminishes the reliability of the etching process.

Accordingly, in this conventional chemical bath, a worker must continually check whether the inner bath is horizontally balanced using a leveling instrument during the etching process. If the chemical bath is not balanced, the worker must adjusting the horizontal balance adjusting units, generally using screws or the like, to maintain the horizontal balance of the inner bath.

Etching by immersion is described in a number of U.S. patents. For example, U.S. Pat. No. 4,462,856 issued to M. Abe, et al. deals with a system adapted to etch an aluminum film on a semiconductor wafer into a predetermined pattern by immersing the film in an etching solution. The system comprises a voltage detecting circuit for detecting a voltage created between a platinum electrode and the aluminum film on the semiconductor wafer, which are immersed in the etching solution. A comparator compares a reference voltage with the voltage detected by the voltage detecting circuit to produce an output signal, and a timer for starting a time count operation upon receipt of the output signal from the comparator and for producing an etching completion signal when it continuously receives the output signal from the comparator for a predetermined time period.

U.S. Pat. Nos. 5,788,800 and 5,904,572 issued to K. Lee, et al., disclose a wet etching station and a wet etching method adapted for utilizing the station. The etching station comprises a bath apparatus containing a chemical etchant. A a plurality of cooling lines are installed in a lower portion of the bath apparatus and are positioned such that they can make contact with the chemical etchant of the bath. The wet etching method adapted for utilizing the etching station provides for channeling a coolant through the cooling lines, the coolant having a lower temperature than the chemical etchant of the bath, and thereby providing a higher relative temperature for the etchant in the upper portion of the bath relative to the etchant in the lower portion of the bath; and immersing a wafer to be etched in the etchant for an amount of time. Thus, a large-diameter wafer can be uniformly etched.

Where etchants containing one or more viscous chemicals are used, frequent and vigorous mixing to keep the chemicals from separating while in the bath is required. For example, an etchant of sulfuric acid and hydrogen peroxide can be used for cobalt silicide selective etching. Sulfuric acid is viscous and tends to separate from the hydrogen peroxide. Even the exothermic reaction caused by mixing the two chemicals is insufficient to keep the etchant properly mixed. Accordingly, the etchant must be agitated while the wafers are in the bath to secure uniformity of etching.

In the U.S. Pat. No. 6,054,062 issued to J. Calio, et al., a method and apparatus for agitating an etchant contained within a bath are disclosed. A wafer is immersed in a bath containing an etchant that is continuously mixed by release of a gas, preferably nitrogen, into the bath at a sufficient flow rate to agitate the etchant and assure a robust and substantially uniform selective etching process. The apparatus comprises valve assembly that receives gas from a source of gas under pressure and controls the flow rate and release pressure of the gas. In addition, the valve assembly contains an on/off valve that, when turned on, releases gas for a predetermined time period. Accordingly, a single operation of the on/off valve releases gas for the duration of a single selective etching cycle. A dispersion plate receives the gas from the valve assembly for release into the bath. The released gas passes through the baffle distribution plate that distributes the gas throughout the bath. The flowing gas agitates the etchant and the amount of agitation is controlled by controlling the pressure and flow rate of the gas.

As suggested in U.S. Pat. No. 6,071,373 issued to Jung-ho Kang et al., a chemical bath of an overflow-type includes a plurality of holes on inner bath sidewalls. The holes are formed in such a manner that they are spaced apart from the upper end of the inner bath at a predetermined distance. In this chemical bath, the chemical in the inner bath flows over the upper end of the inner bath into the outer bath and is simultaneously is discharged to the outer bath through the holes. Accordingly, unless either of the opposed sidewalls slopes lower than another by over a predetermined value, the chemical can flow continuously at nearly the same rate at both sidewalls of the inner bath. This reduces the difference of the etching rate between the respective wafers caused by the difference of the position of the wafers immersed in the chemical in the inner bath and leads to an improvement in the reliability and of the etching process and uniformity of its results.

U.S. Pat. No. 6,090,720 issued to T. Sato discloses a wet etching method and apparatus, in which a wafer is processed so as to have a good flatness by making uniform a travel distance and a traveling velocity of an arbitrary point on a wafer surface relative to an etching solution, while rotating the wafer in the etching solution. An etching solution vessel comprises a pair of walls parallel to a plane of rotation of a wafer; and walls of curved surfaces, which intersect the pairs of walls at a right angle. The centers of curvature of the walls are the same. The walls are spaced apart from each other along a radius of curvature with a distance of d therebetween. The etching solution is fed from a lower part of the vessel. A flow velocity of the etching solution is adjusted at an arbitrary point between the pair of curved surfaces just before a stream of the solution contacts with a wafer rotating in the etching solution so that the flow velocity is a velocity (r.omega.), which is obtained by multiplying a distance r between the center of curvature and the arbitrary point with an angular velocity. omega. of the wafer or its approximation.

In yet another U.S. Pat. No. 6,123,865 issued to Wei-Chin Lin et al., a method for improving etch uniformity during a wet etching process is disclosed. According to the invention, the method is characterized by forming a water film over the wafer surface prior to etching the surface layer with a viscous acid solution. The water film helps the subsequent viscous etchant to be spread across the wafer surface more uniformly to thereby improve the etch uniformity.

The wet etching process of this invention comprises the steps of rotating a semiconductor wafer having a layer formed thereon at a first speed, supplying deionized water to the wafer to form a water film over the wafer surface; and supplying an acid solution to the wafer for etching the layer before the water film is dried. According to the process of the invention, in the course of supplying deionized water, the wafer is preferably rotated at a relatively low speed to prevent the dispensed water from splashing, destroying film uniformity. The deionized water is supplied at a flow rate of about 0.2-1 l/min for about 1-6 seconds. After the deionized water has been supplied, it is more preferable that the wafer is rotated at a higher speed for a time, e.g., 2 seconds, to expel excess water off the wafer and thin the remaining water into a uniform film. If the excess water is not removed, a great deal of heat capable of damaging semiconductor devices is created upon the supply of acid solutions.

This etching process is particularly advantageous when a viscous etchant, such as a sulfuric acid based etchant, is employed. Etching solutions suitable for use in this invention include the solutions of sulfuric acid, hydrofluoric acid, nitric acid, phosphoric acid, and acetic acid, or a mixture thereof. The layer formed over the wafer being etched can be a metal layer formed of copper or aluminum, or a nonmetal layer formed of silicon, silicon oxide, borophosphosilicate glass, phosphosilicate glass, borosilicate glass, silicon nitride, silicon oxynitride, or spin-on glass.

As shown in FIG. 1, a conventional wafer holder 10 is shown comprising a back plate 12 with arms 14 and a wafer guide 16, which are rigidly attached to the plate 12. The wafer holder 10 is a portion of a wet etching station, which is symbolically represented by an arm 18 rigidly affixed to the back plate 12. Wafers carried by the holder 10 are represented in FIG. 1 by a wafer 20.

The above-described prior art methods and apparatus have a common drawback in that when the wafers go inside the chemical bath, they follow the sequence that, when the process starts, the bottom portion of the wafers go down into the bath first, and, upon completing the process, the bottom portion is taken out last. Consequently, the etching time for the top portion of the wafers is less than for the bottom one. This affects the etching uniformity of the wafers.

### SUMMARY OF THE INVENTION

Therefore, the primary object of the present invention is to provide a method of etching semiconductor wafers that, upon keeping the advantages of the prior art methods, would be free from the drawback affecting etching uniformity.

More specific object of the invention is to provide a wafer lifter for a chemical bath that would contribute to etching uniformity.

According to the invention, the above goals are attained by providing that the portion of a wafer that is immersed into an etchant solution first, leaves the solution also first, whereas the portion that enters the solution last, leaves the solution last as well, to thereby equalize etching time for various areas of the wafer, whereby higher wafer etching uniformity is attained.

Further according to the invention, to attain the above order of subjecting the wafer portions upon dipping to the influence of the etchant solution, the wafer is rotated upside down while in the etchant solution.

The axis of the rotation is selected normal to the plane of the wafer.

A wafer holder unit according to the present invention comprises a wafer holder made up of a backing plate, holding arms and a wafer guide, and means for turning the wafer holder upside down.

The turning means may include an electric motor and means for translating motor rotation into wafer holder upside-down turning, which translating means may in turn include a belt transmission.

### BRIEF DESCRIPTION OF THE DRAWINGS

The above objects and advantages of the present invention will become more apparent by describing a preferred embodiment thereof in detail and with reference to the attached drawings, in which:

FIG. 1 is a perspective view showing a conventional wafer holder in a wet etching device;

FIG. 2 is a perspective view of a wafer holder in a wet etching device according to an embodiment of the present invention; and

FIG. 3 is a front view of the wafer holder in a wet etching device of FIG. 2.

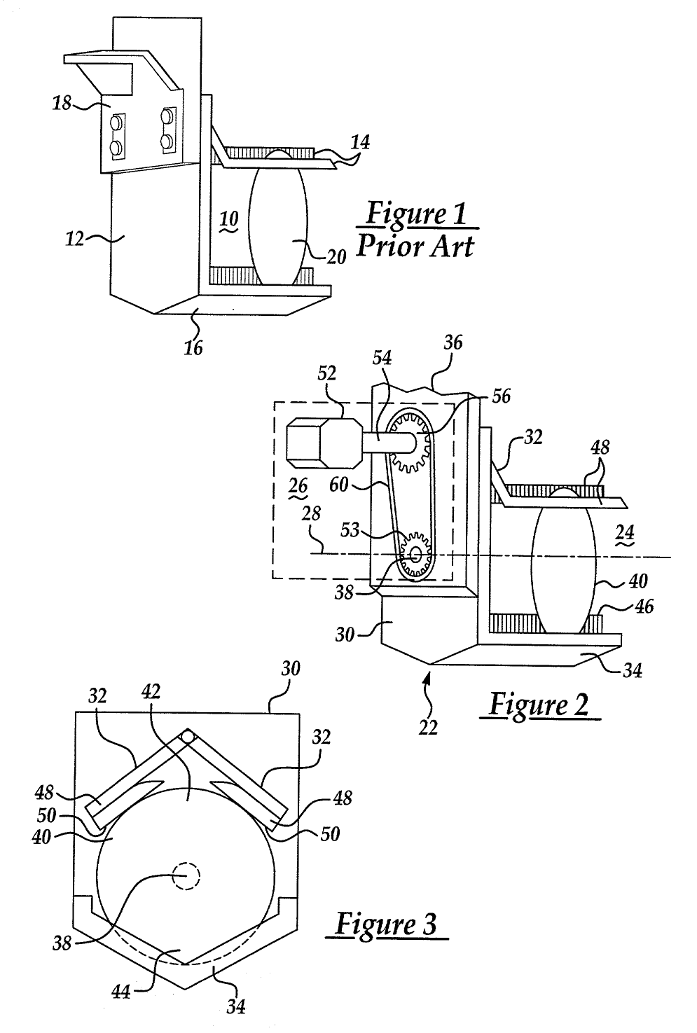

### DETAILED DESCRIPTION OF THE PREFERRED EMBODIMENT

Referring now to FIG. 2, a wafer holder unit 22 is shown comprising a wafer holder 24 and means 26 for turning the wafer holder 24 around axis 28. The wafer holder 24 comprises a back plate 30, to which arms 32 and a wafer guide 34 are permanently attached. The wafer holder unit 22 is a portion of a wet etching station, which is symbolically represented by a plate 36 and, being irrelevant to the present invention, is not discussed in more detail.

The wafer holder 24 is attached, by its back plate 30, to the plate 36 and adapted to be turnable around the axis 28. The connection between the back plate 30 and the plate 36 may be implemented, for example, by means of a shaft 38 coaxial with the axis 28. The shaft supports the back plate 30, which rigidly sits on the shaft. On the other hand, the shaft 38 mounted in the plate 36, for example in a bearing (not shown), is adapted to turn and thus carry away the back plate 30, and the wafer holder 24 as a whole, therewith.

Wafers carried by the wafer holder 24 are represented in FIG. 2 by a wafer 40 that, for the reasons more fully understood from the description hereinbelow, can be conveniently defined by its top portion 42 and a bottom portion 44 and rests in one of the plurality recesses 46 in the wafer guide and is supported at the top by the arms 32. As can be best seen in FIG. 3, the support is realized by portions 48 of the arms 32, whose inner surface 50 can be covered by a material hard enough to perform its supporting functions, soft enough not to damage the wafers, and chemically resistant enough to withstand attacking by the etchant solution.

The means 26 for turning the wafer holder 24 around the axis 28 are shown in FIG. 2 as a motor 52, which preferably, though not in a limited way, can be a stepping motor. The motor 52 is provided with a driving shaft 54, for example a gear shaft. The shaft 54 can be mounted in the plate 36 in the way similar to that of the shaft 38—in a bearing (not shown).

The driving shaft 54 is provided with a gear 56, and the driven shaft 38 is provided with a gear 58, and the shafts are connected to each other through a chain transmission 60.

In operation, when the wafer holder 24 with wafers therein is immersed into the chemical bath filled with etchant solution (neither the bath nor the solution is shown), the motor 52 is turned on and rotates the holder 24 by 180°. Therefore, after completing the etching, when the wafer holder 24 is moved out of the etchant, the bottom portion 44 of the wafers that entered the etchant first leaves it also first, whereas the top portion 42 that entered the etchant last leaves it also last. Therefore, the time the top portion and the bottom portion were subjected to etching is equalized therefor and the etching becomes more uniform for the wafers.

Though the present invention has been fully described in the foregoing preferred embodiment, it is to be clearly understood that various modifications apparent to those skilled in the art can be made without departing from the spirit and scope of the invention. All of these modifications are therefore construed as being covered by the claims that follow.

What is claimed is:

1. Method of wet etching a semiconductor wafer by immersing the same into a chemical bath filled with etchant solution, said wafer being defined by its top portion and its bottom portion, said bottom portion being immersed to the bath first, keeping said wafer in said etchant solution for predetermined time, and taking said wafer out of said etchant solution upon completing etching, said top portion of said wafer leaving said etchant solution last, to thereby equalize etching time for various areas of said wafer, whereby higher wafer etching uniformity is attained.

2. The method as claimed in claim 1, wherein said taking said wafer out of said etchant solution with said top portion leaving said etchant solution last is realized by turning said wafer upside down while in said etchant solution.

3. The method as claimed in claim 2, wherein said turning said wafer upside down is carried out around an axis normal to a plane thereof.

4. A wet etching station comprising a wafer holder carrying at least one wafer, a chemical bath filled with an etchant solution, means for immersing said wafer holder into said etchant solution, and means for turning said wafer holder upside down while in etchant, thus providing for equal etching time for various areas of said at least one wafer, to thereby contribute to higher wafer etching uniformity.

5. The station as claimed in claim 4, wherein said turning is carried out around an axis normal to a plane of said at least one wafer.

6. The station as claimed in claim 4, wherein said turning means include an electric motor.

7. In a wet etching station, a wafer holder unit comprising a wafer holder having a back plate, two arms and a wafer guide, said two arms and said wafer guide being attached to said back plate and adapted to accommodate a wafer a position on said wafer holder and keep same in said position; and means for turning said wafer holder upside down.

8. The wafer holder unit as claimed in claim 7, wherein said turning means includes an electric motor and means for translating rotation from said electric motor to said wafer holder.

9. The wafer holder unit as claimed in claim 8, wherein said translating means includes a belt transmission.
